(19) United States
(12) Patent Application Publication
(10) Pub. No.: US 2006/0102323 A1
(43) Pub. Date: May 18, 2006

(54) Radially shaped heat pipe

(76) Inventor: Prosenjit Ghosh, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/367,059

(22) Filed: Feb. 14, 2003

(51) Int. Cl. F28F 7/00; F28D 15/00; H05K 7/20

(52) U.S. Cl. 165/104.33; 165/80.3; 165/104.21; 361/700

(57) ABSTRACT

A radial heat pipe is disclosed. In one embodiment, the radial heat pipe is to be wrapped around a perimeter edge of a thermally conductive member, the heat pipe having a circular shape, the heat pipe having a cross-section radius equal to or less than a height of the thermally conductive member.

### FIELD OF THE INVENTION

Embodiments of the present invention relate to heat management and more particularly to heat management using thermal conductors.

### BACKGROUND

Thermal management can be critical in many applications. Excessive heat can cause damage to or degrade the performance of mechanical, chemical, electric, and other types of devices. Heat management becomes more critical as technology advances and newer devices continue to become smaller and more complex, and as a result run hotter.

Modern electronic circuits, because of their high density and small size, often generate a substantial amount of heat. Complex integrated circuits (ICs), especially microprocessors, generate so much heat that they are often unable to operate without some sort of cooling system. Further, even if an IC is able to operate, excess heat can degrade an IC's performance and can adversely affect its reliability over time. Inadequate cooling can cause problems in central processing units (CPUs) used in personal computers (PCs), which can result in system crashes, lockups, surprise reboots, and other errors. The risk of such problems can become especially acute in the tight confines found inside laptop computers and other portable computing and electronic devices.

Prior methods for dealing with such cooling problems have included using heat sinks, fans, and combinations of heat sinks and fans attached to ICs and other circuitry in order to cool them. However, in many applications, including portable and handheld computers, computers with powerful processors, and other devices that are small or have limited space, these methods may provide inadequate cooling.

As illustrated in FIG. 1, current practices include attaching a heat pipe (HP) 102 to a thermal block 104 is across the center of the block. This is achieved by one of two ways: flattening a portion of the round HP and then laying it in a rectangular groove 106 of the block 104 (as illustrated in FIG. 2); or laying the round HP on a half-cylindrical trough.

Both options have limitations. Option 1 is often more attractive for thin systems, although it is prone to irregular surface contact between the HP and the block due to the flattening fabrication process, thereby causing high thermal solution performance variance in especially in high volume manufacturing. Although option 2 provides more consistent performance, it is marred for thin systems due to its increased vertical height relative to option 1.

### BRIEF DESCRIPTION OF THE DRAWINGS

FIG. 1 is a perspective illustration of a prior art heat pipe and thermal block.

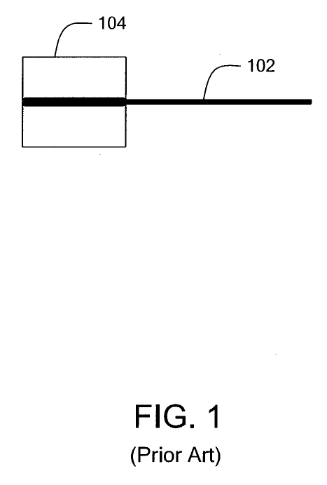

FIG. 2 is a cut-away illustration of a prior art thermal block.

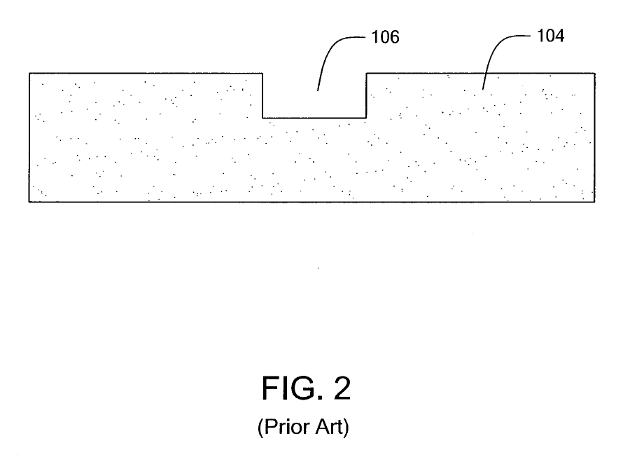

FIG. 3 is a perspective illustration of a radial heat pipe according to an embodiment.

FIG. 4 is a cut-away illustration of a thermally conductive member according to one embodiment.

FIG. 5 is a cut-away illustration of a thermally conductive member according to an alternative embodiment.

FIG. 6 is a perspective view of a system according to one.

### DETAILED DESCRIPTION

Embodiments of a heat pipe having a radial shape to be fitted around a perimeter edge of a thermally conductive member, are disclosed. In the following description, numerous specific details are set forth. However, it is understood that embodiments may be practiced without these specific details. In other instances, well-known circuits, structures and techniques have not been shown in detail in order not to obscure the understanding of this description.

Reference throughout this specification to “one embodiment” or “an embodiment” indicate that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

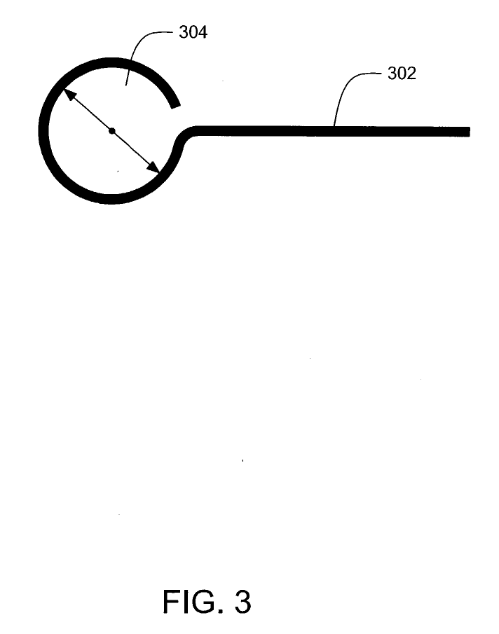

In one embodiment, as illustrated in FIG. 3, the heat pipe 302 is fitted around a perimeter edge of a thermally conductive member 304 (e.g., a heat block, thermal block). In one embodiment, the heat pipe is shaped in a radial configuration that is fitted in contact around a perimeter edge of a radial shaped thermally conductive heat block.

In an alternative embodiment, the heat pipe has a shape other than a radial shape. For example, the heat pipe in alternative embodiments may have a shape of an elliptical, square, rectangle, or other shapes, and be fitted around a thermally conductive member having a corresponding shape. Furthermore, the diameter of the thermally conductive block and heat pipe may vary in different embodiments.

The thermally conductive member is placed in contact with a surface of a heat generating device (e.g., a central processing unit (CPU), a graphics processor, a chip set, a memory controller, or other circuits). The thermally conductive member absorbs at least part of the heat generated by the heat generating device. The heat absorbed by the thermally conductive member is then absorbed by the heat pipe in contact with the thermally conductive member. Heat absorbed by the heat pipe is then transferred to an opposite end of the heat pipe, where the heat may be dissipated by the use of a heat exchanger (one embodiment of which is described in more detail below).

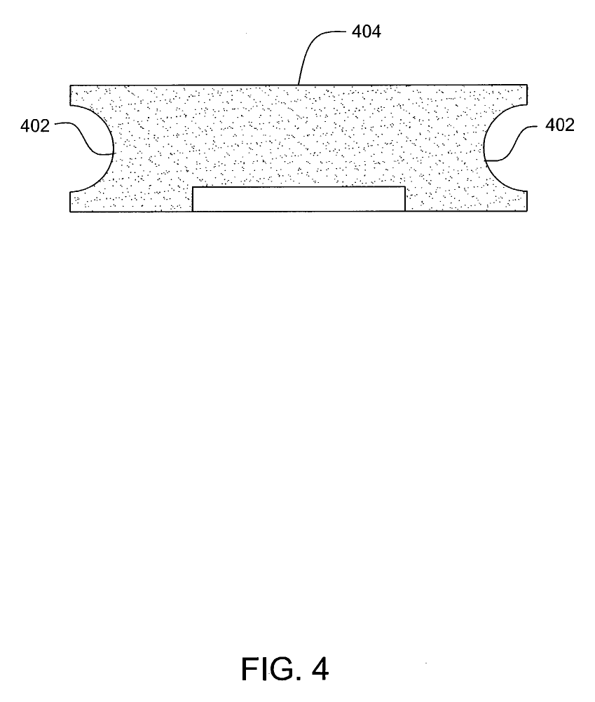

As illustrated in FIG. 4, in one embodiment, the heat pipe is fitted into a curved aperture 402 on perimeter edge of a thermally conductive block 404. As illustrated in FIG. 4, the radius of the curved aperture 402 is slightly larger than a radius of the heat pipe to allow the heat pipe to be fitted within the aperture. As a result, in one embodiment, when the heat pipe is fitted around a perimeter edge of the thermally conductive member, the heat pipe had a height equal to or less than a height of the thermally conductive member, and thereby does not increase the need for additional height space within a system.

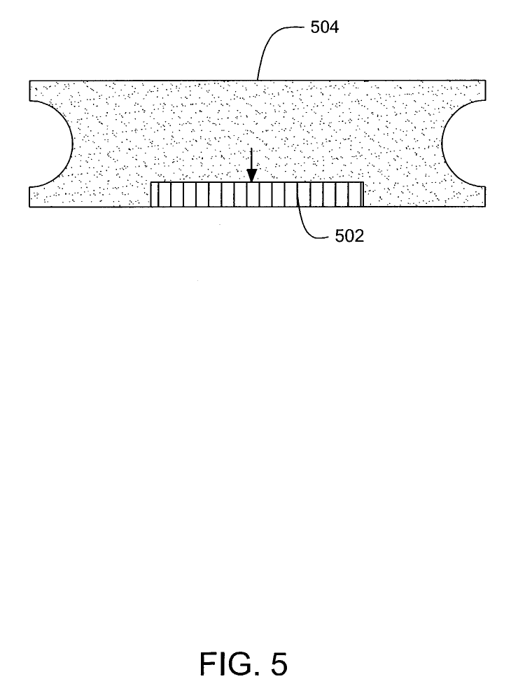

As illustrated in FIG. 5, in one embodiment, the thermally conductive member 504 includes an aperture 502 on a bottom surface of the thermally conductive member 504. The aperture 502 allows the thermally conductive member 504 to receive the heat generating device and to have the thermally conductive member encompass the heat generating device. In one embodiment, the aperture on the bottom surface of the thermally conductive member 504 has a height and length slightly larger than a height and diagonal length of the heat generating device, which it is to cover.

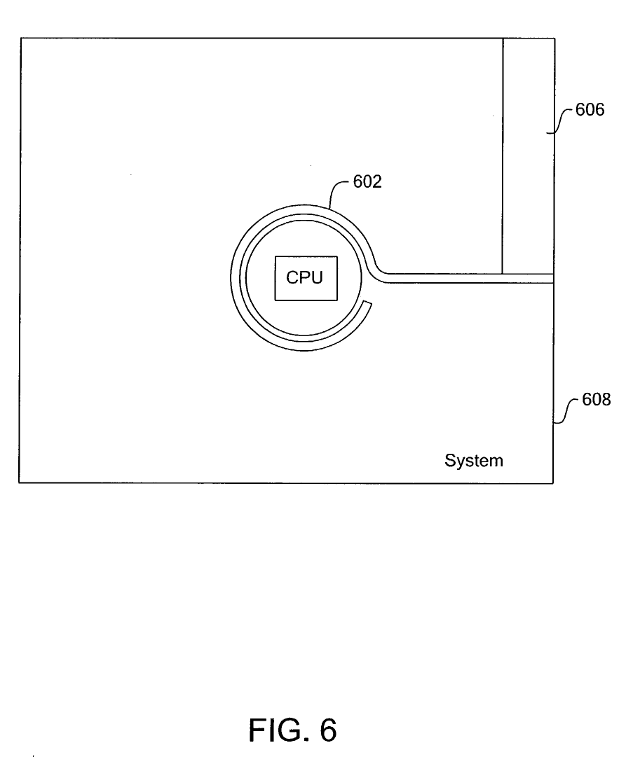

As discussed above, in one embodiment, an end of the heat pipe, opposite an end in contact with the thermally conductive member, may terminate at a heat exchanger or heat sink. In one embodiment, as illustrated in FIG. 6, the heat pipe 602 terminates in a heat sink 606 integrated in a wall 608 of a computing device 610. The heat sink integrated in the wall of the computing device, having a height dimension equal to or less than a height of the computing device.

In one embodiment, the heat sink includes a plurality of fins. The fins are spaced apart to allow ambient air from outside the computing device to naturally flow across the fins of the heat sink to dissipate the heat resident in the fins, which had been transferred from the heat generating device. In one embodiment, each fin of the heat sink is 16 mm in height, 6 mm in width, and 2 mm in depth. In one embodiment, the space between each pair of fins is 1.5 mm. In an alternative embodiment, alternative heat sink and heat exchangers may be used.

These embodiments have been described with reference to specific exemplary embodiments thereof. It will, however, be evident to persons having the benefit of this disclosure that various modifications and changes may be made to these embodiments without departing from the broader spirit and scope of the invention. The specification and drawings are, accordingly, to be regarded in an illustrative rather than a restrictive sense.

What is claimed is:

1. An apparatus, comprising:
a heat pipe having a radial shape to be fitted against a perimeter edge of a thermally conductive member.

2. The apparatus of claim 1, wherein the thermally conductive member has a radial shape.

3. The apparatus of claim 1, wherein a cross-section of the heat pipe has a radius equal to or less than a height of the thermally conductive member

4. The apparatus of claim 2, wherein the heat pipe to be fitted in a curve shaped aperture on the perimeter of the thermally conductive member.

5. The apparatus device of claim 1, wherein the thermally conductive member further comprises an aperture on a bottom side of the member, the aperture to receive a heat generating device, to have the thermally conductive member encompass the heat generating device.

6. The apparatus of claim 1, the heat pipe having a first end terminating at the thermally conductive member, and a second end terminating at a heat exchanger.

7. The apparatus of claim 6, wherein the heat exchanger is integrated in a chassis wall of a system.

8. A system comprising:
a heat generating device;
a thermally conductive member to absorb heat generated by the heat generating device; and
a heat pipe having a radial shape, the heat pipe positioned adjacent to a perimeter edge of the thermally conductive block.

9. The system of claim 8, wherein the wherein the thermally conductive member has a radial shape.

10. The system of claim 8, wherein a cross-section of the heat pipe has a radius equal to or less than a height of the thermally conductive member.

11. The system of claim 8, wherein the heat pipe is positioned in a curve shaped aperture on the perimeter of the thermally conductive member.

12. The system of claim 8, wherein the thermally conductive member further comprises an aperture on a bottom side of the member, the aperture to receive a heat generating device, to have the thermally conductive member encompass the heat generating device.

13. The system of claim 8, wherein the heat pipe having a first end terminating at the thermally conductive member, and a second end terminating at a heat exchanger.

14. The system of claim 13, wherein the heat exchanger is integrated in a chassis wall of a system.

15. An apparatus comprising:
a heat pipe to be wrapped around a perimeter edge of a thermally conductive member, the heat pipe having a circular shape, the heat pipe having a cross-section radius equal to or less than a height of the thermally conductive member.

16. The apparatus of claim 15, wherein the heat pipe is fitted in a curve shaped aperture on the perimeter of the thermally conductive member.

17. The apparatus device of claim 15, wherein the heat pipe having a first end terminating at the thermally conductive member, and a second end terminating at a heat exchanger, the heat exchanger integrated in a chassis wall of a system.
